(19) United States
(12) Patent Application Publication
(10) Pub. No.: US 2008/0054440 A1
(43) Pub. Date: Mar. 6, 2008

(54) Wire bonding method, wire bonding apparatus and semiconductor device

(75) Inventors: Takayoshi Matsumura, Kawasaki (JP); Hidehiko Kira, Kawasaki (JP); Naoki Ishikawa, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/651,515

(22) Filed: Jan. 10, 2007

(30) Foreign Application Priority Data
Aug. 30, 2006 (JP) 2006-233352

(51) Int. Cl. H01L 23/48

(52) U.S. Cl. 257/690

(57) ABSTRACT

The wire bonding method includes: a first connecting step of supplying an end of wire for electric wiring to a first electrode on an IC chip and applying vibration to the wire, thereby connecting the end of the wire to the first electrode; a wire stretching step of stretching the wire whose end is connected to the first electrode up to a second electrode on a different member from the IC chip; and a second connecting step of connecting the wire to the second electrode by applying vibration, in an extension direction of the wire stretched from the first electrode to the second electrode, to a portion of the wire overlapping the second electrode.

### BACKGROUND OF THE INVENTION

1. Field of the Invention

The present invention relates to a wire bonding method and a wire bonding apparatus for connecting a multiplicity of electrodes with wire for electric wiring and a semiconductor device in which a multiplicity of electrodes are connected with wire for electric wiring.

2. Description of the Related Art

In recent years, the size of the IC chip has been reduced rapidly with the trend of miniaturization of semiconductor integrated circuit. For such a small IC chip to conduct electricity securely, it has been demanded to connect minute electrodes provided on the IC chip with electrodes provided on a substrate in which that IC chip is placed at a high accuracy, by using wire for electric wiring.

As a method for connecting a multiplicity of electrodes with wire, the wire bonding method using ultrasonic wave has been widely used. Basically, first, an end of wire is pressed against an electrode on the IC chip and ultrasonic wave is applied to that wire so that the wire is bonded to the electrode on the IC chip (first bonding). Subsequently, wire after the first bonding is stretched up to an electrode on a substrate and ultrasonic wave is applied to the wire pressed against the electrode on the substrate so that the wire is bonded to the electrode on the substrate (second bonding). Use of ultrasonic wave for bonding wire enables the wire to be bonded to a minute electrode, so that the IC chip can conduct electricity securely.

However, if the proper oscillation frequency of wire stretched from an electrode at a first bonding position to an electrode at a second bonding position coincides with oscillation frequency of ultrasonic wave applied to the wire at the time of the second bonding, the wire resonates so that it vibrates largely, thereby sometimes resulting in separation of the wire bonded to the electrode at the first bonding position.

As regards the above problem, Japanese Patent Application Laid-Open (JP-A) 2004-296468 has described a wire bonding method in which wire is bent to a shape having two or more nodes, when being stretched from an electrode at a first bonding position to an electrode at a second bonding position, by using a fact that resonance frequency of the wire changes depending on the length of wire. Japanese Patent Application Laid-Open (JP-A) has described another wire bonding method of executing the second bonding with wire bonded to the electrode by the first bonding pressed. Separation of the wire due to resonance can be avoided by the wire bonding methods described in JP-A 2004-296468 and JP-A 2002-110885.

However, in case of the wire bonding method of JP-A No. 2004-296468, wire needs to be longer by an amount corresponding to bent sections and if a multiplicity of wires are bonded to a single IC chip, these wires jam so as to complicate wiring, so that wires may make contact with each other thereby causing electric short-circuit. Further, in case of the wire bonding method of JP-A No. 2002-110885, space for disposing a clamper needs to be provided to press the wire bonded to the electrode, thereby resulting in enlargement of the substrate and IC chip.

### SUMMARY OF THE INVENTION

The present invention has been made in view of the above circumstances and provides a wire bonding method and wire bonding apparatus capable of avoiding separation of wire due to resonance as well as suppressing enlargement of the IC chip and complication of wiring.

According to an aspect of the present invention, there is provided a wire bonding method including:

a first connecting step of supplying an end of wire for electric wiring to a first electrode on an IC chip and applying vibration to the wire, thereby connecting the end of the wire to the first electrode;

a wire stretching step of stretching the wire whose end is connected to the first electrode up to a second electrode on a different member from the IC chip; and

a second connecting step of connecting the wire to the second electrode by applying vibration, in an extension direction of the wire stretched from the first electrode to the second electrode, to a portion of the wire overlapping the second electrode.

As a result of analyzing stress applied to a connecting section between the wire and the first electrode at the time of second bonding, it has been found that as the direction of vibration applied to the wire approaches perpendicularity relative to the extension direction of the wire, the wire resonates so that stress applied to the connecting section with the first electrode increases and on the other hand, if the extension direction of the wire coincides with the vibration direction, little stress is applied to the connecting section with the first electrode. According to the wire bonding method of the present invention, the wire connected to the first electrode is stretched up to the second electrode and vibration in the extension direction of the wire is applied to the portion of the wire overlapping the second electrode. Therefore, separation of the wire due to resonance can be avoided without changing the length of the wire, the bonding position and the like, thereby making it possible to connect the IC chip and the substrate to each other securely.

According to the wire bonding method of the present invention, preferably, the vibrating unit including:

a capillary which applies vibration to the wire supplied to an electrode; and

plural vibrating members which vibrate the capillary in different vibration directions,

wherein the second connecting step is a step of causing the capillary to apply vibration in the extension direction to the portion of the wire overlapping the second electrode, by adjusting amplitude of each vibration of the plural vibrating members.

The direction of vibration applied to the wire can be matched with the extension direction of the wire easily by adjusting the amplitude of each vibration of the plural vibrating members and thus separation of the wire due to resonance can be avoided.

In the wire bonding method of the present invention, preferably, the plural vibrating members including:

a first vibrating member which vibrates in a predetermined first direction; and

a second vibrating member which vibrates in a second direction perpendicular to the first direction,

wherein the second connecting step is a step of, when assuming that an angle formed between the extension direction and the first direction is θ and the amplitude of vibration applied to the wire is W, vibrating the first vibrating member at an amplitude of W cos θ while vibrating the second vibrating member at an amplitude of W sin θ, thereby causing the capillary to apply synthetic vibration by the first vibrating member and the second vibrating member to the portion of the wire overlapping the second electrode.

According to the preferred wire bonding method of the present invention, the wire can be vibrated at the amplitude W in the extension direction of the wire and the wire can be connected securely to the first electrode and the second electrode.

In the wire bonding method of the present invention, preferably, the first connecting step is a step of applying ultrasonic wave to the wire and the second connecting step is a step of applying ultrasonic wave to the portion of the wire overlapping the second electrode.

According to another aspect of the present invention, there is provided a wire bonding apparatus including:

a mounting base on which an IC chip having a first electrode and a member to be connected are mounted, the member being different from the IC chip and having a second electrode to be connected to the first electrode;

a vibrating unit including a capillary and a vibrating member which vibrates the capillary, the capillary supplying wire for electric wiring to an electrode and connecting the wire to the electrode by applying vibration to the wire; and

a control unit which causes the capillary to:

supply an end of the wire to the first electrode on an IC chip mounted on the mounting base and connect the end of the wire to the first electrode by applying vibration to the wire;

stretch the wire whose end is connected to the first electrode up to a second electrode on the member; and

apply vibration in an extension direction of the wire to a portion thereof overlapping the second electrode of the wire stretched up to the second electrode, thereby connecting the wire to the second electrode.

In the wire bonding apparatus of the present invention, the fault that the wire connected to the first electrode is separated due to resonance of the wire can be avoided because vibration in the extension direction of the wire is applied to the wire stretched from the first electrode to the second electrode.

In the wire bonding apparatus of the present invention, preferably, the vibrating unit includes plural vibrating members which vibrate the capillary to vibrate in different directions,

wherein the control unit causes the capillary to apply vibration in the extension direction to the portion of the wire overlapping the second electrode, by adjusting the amplitude of each vibration of the plural vibrating members after the wire is stretched to the second electrode.

The direction of vibration applied to the wire can be adjusted easily by provision of the plural vibrating members.

In the wire bonding apparatus of the present invention, preferably, the plural vibrating members includes:

a first vibrating member which vibrates in a predetermined first direction; and

a second vibrating member which vibrates in a second direction perpendicular to the first direction, wherein the control section, when it is assumed that an angle formed between the extension direction and the first direction is θ and the amplitude of vibration applied to the wire is W, vibrates the first vibrating member at an amplitude of W cos θ while vibrating the second vibrating member at an amplitude of W sin θ, thereby causing the capillary to apply synthetic vibration by the first vibrating member and the second vibrating member to the portion of the wire overlapping the second electrode.

The preferred wire bonding apparatus of the present invention enables the wire to be securely connected to the first electrode and the second electrode.

In the wire bonding apparatus of the present invention, preferably, the vibrating unit applies ultrasonic wave to the wire.

The wire is connected to the electrode securely by utilizing ultrasonic vibration.

According to still another aspect of the present invention, there is provided a semiconductor device which is manufactured through:

a first connecting step of supplying an end of wire for electric wiring to a first electrode on an IC chip and connecting the wire to the first electrode by applying vibration to the wire;

a wire stretching step of stretching the wire whose end is connected to the first electrode up to a second electrode on a different member from the IC chip; and

a second connecting step of connecting the wire to the second electrode by applying vibration, in an extension direction of the wire stretched from the first electrode to the second electrode, to a portion of the wire overlapping the second electrode.

In the semiconductor device of the present invention, the wire can be bonded securely to a minute electrode, which secures electric conductibility of the IC chip and the like.

In the semiconductor device of the present invention, preferably, the first connecting step is a step of applying ultrasonic wave to the wire and the second connecting step is a step of applying ultrasonic wave to the portion of the wire overlapping the second electrode.

Consequently, the wire can be connected to the electrode securely by applying ultrasonic wave to the wire.

As described above, the present invention can prevent separation of the wire due to resonance as well as suppress enlargement in the size of the IC chip and the like and complexity of wiring.

### BRIEF DESCRIPTION OF THE DRAWINGS

FIG. 1 is a schematic structure diagram of a wire bonding apparatus according to an embodiment of the present invention;

FIG. 2 is a schematic structure diagram of a substrate and IC chip;

FIG. 3 is a diagram for explaining an embodiment of wire bonding method of the present invention;

FIG. 4 is a diagram showing a relationship between positions of the substrate and IC pad and vibration direction of ultrasonic wave to be applied to the wire;

FIG. 5 is a diagram showing an IC chip and substrate to which wires are connected;

FIG. 6 is a schematic structure diagram of a wire bonding apparatus according to a second embodiment of the present invention;

FIG. 7 is a diagram showing a relationship between positions of an electrode pad and inner lead and vibration applied to the wire; and

FIG. 8 is a graph showing a relationship between the frequency of ultrasonic wave applied to an ultrasonic wave horn and stress applied to a front end of wire connected to an electrode pad.

### DETAILED DESCRIPTION OF THE INVENTION

Hereinafter, embodiments of the present invention will be described with reference to the accompanying drawings.

The wire bonding apparatus according to an embodiment of the present invention is intended to connect a substrate with an IC chip electrically by connecting an inner lead provided on the substrate to an electrode pad provided on the IC chip with wire. Although a variety of electric circuits are connected to an actual substrate as well as the IC chip, only a portion surrounding the IC chip is shown for convenience for representation in order to describe the substrate in this specification.

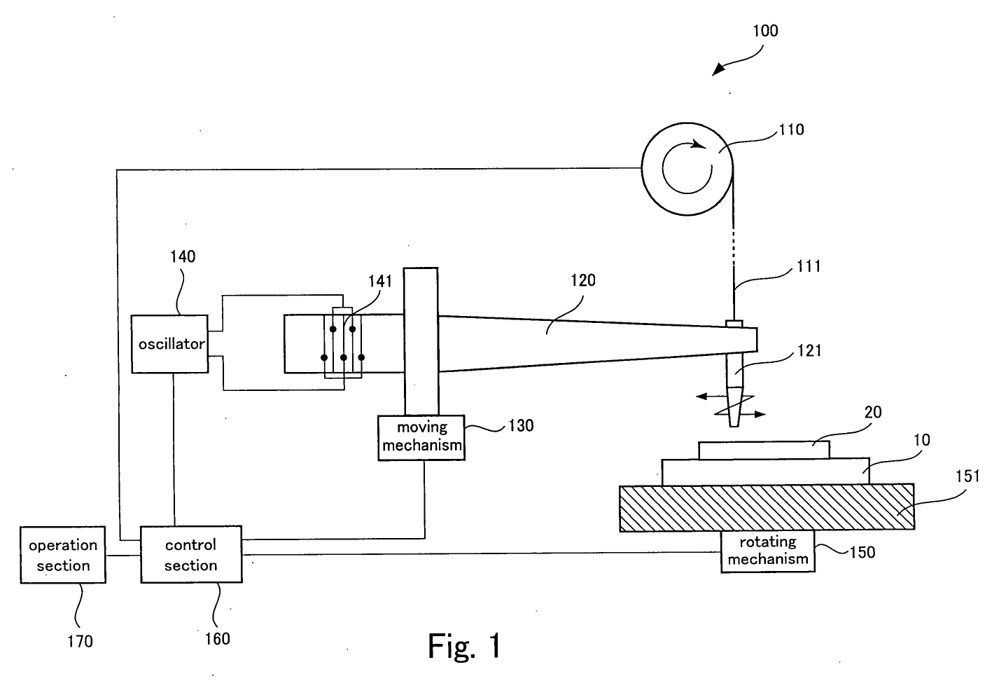

FIG. 1 is a schematic structure diagram of a wire bonding apparatus according to an embodiment of the present invention.

The wire bonding apparatus 100 shown in FIG. 1 includes a wire feeder 110 on which wire 111 is wound, a capillary 121 which supplies the wire 111 wound around the wire feeder 110 to an IC chip 20 and a substrate 1 and vibrates the wire 111, an ultrasonic horn 120 provided with the capillary 121 at its front end so as to vibrate the capillary 121 by applying ultrasonic wave, a moving mechanism 130 for moving the ultrasonic horn 120 vertically and horizontally, a vibrator 141 for applying ultrasonic wave to the ultrasonic horn 120, an oscillator 140 for vibrating the vibrator 141, a mounting base 151 on which a substrate 10 is to be placed, a rotating mechanism 150 for rotating the mounting base 151, an operation section 170 to be operated by a user and a control section 160 for controlling the entire wire bonding apparatus 100 corresponding to an operation of the operation section 170. In this embodiment, the ultrasonic horn 120 is expanded/contracted in the axial direction by the vibrator 141, so that the capillary 121 is vibrated in the axial direction of the ultrasonic horn 120. The capillary 121 corresponds to an example of the capillary of the present invention, the ultrasonic horn 120 corresponds to an example of a vibrating member, and a combination of the ultrasonic horn 120, capillary 121, oscillator 140 and vibrator 141 corresponds to an example of a vibrating unit mentioned in the present invention. Further, the mounting base 151 corresponds to an example of a mounting base of the present invention and the control section 160 corresponds to an example of a control unit of the present invention.

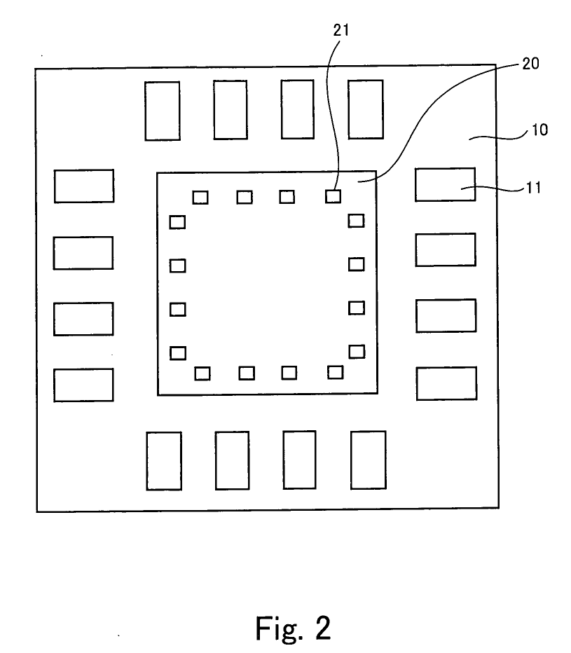

FIG. 2 is a schematic structure diagram of a substrate 10 and an IC chip 20.

The IC chip 20 has a multiplicity of electrode pads 21 with a sequential number and the control section 160 shown in FIG. 1 memorizes respective numbers and positions of the electrode pads 21 with each number in correspondence therebetween. The electrode pad 21 corresponds to an example of the first electrode in the present invention.

The substrate 10 is provided with a multiplicity of the electrode pads 21 and a multiplicity of inner leads 11 to be connected with the respective electrode pads 21. Each inner lead 11 is supplied with the same number as that attached to the electrode pad 21 and the control section 160 memorizes respective numbers and positions of the inner leads 11 each having the number in correspondence therebetween. The inner lead 11 corresponds to an example of the second electrode in the present invention.

Subsequently, the wire bonding method of connecting the inner lead 11 of the substrate 10 to the electrode pad 21 of the IC chip 20 with the wire 111 in the wire bonding apparatus 100 shown in FIG. 1 will be described.

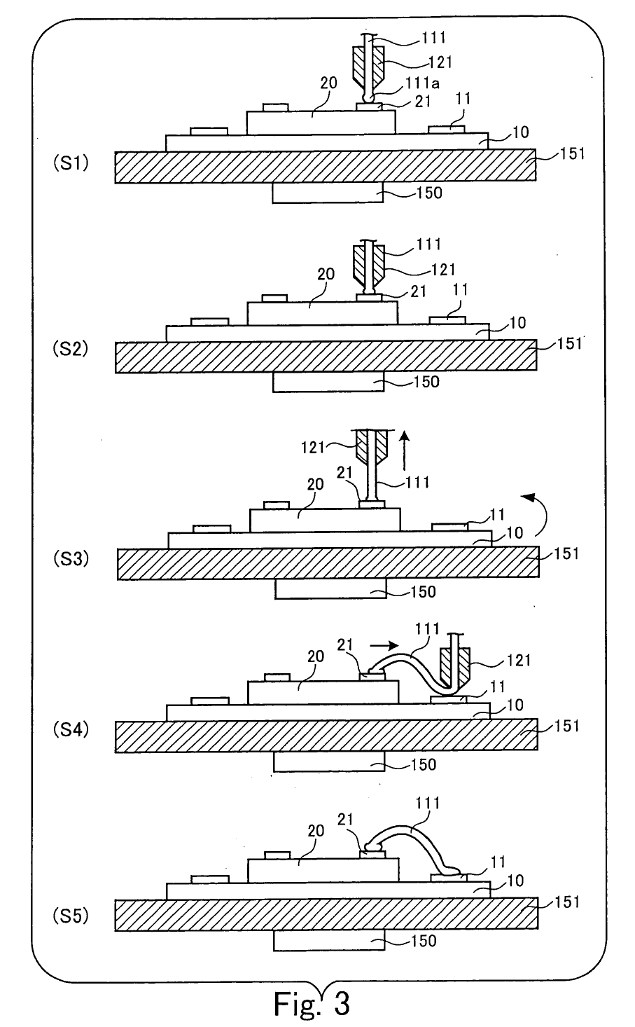

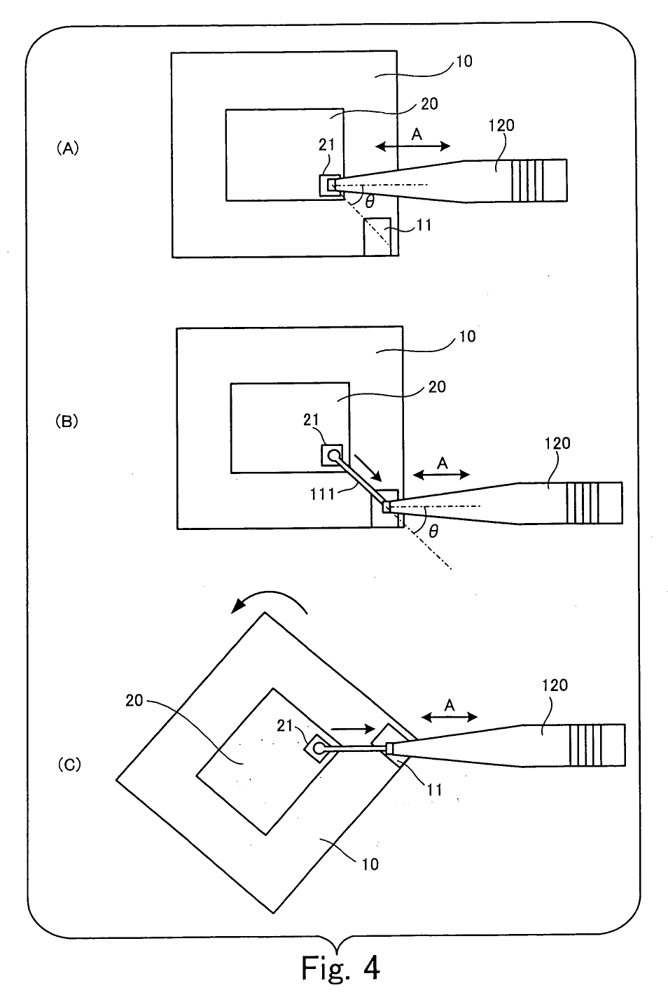

FIG. 3 is a diagram for explaining an embodiment of the wire bonding method of the present invention and FIG. 4 is a diagram showing the relationship between positions of the substrate 10 and IC chip 20 and a vibration direction of ultrasonic wave applied to the wire 111.

If start of wire bonding is instructed when the operation section 170 is operated by user, a position of the electrode pad 21 with a first number “1” is transmitted from the control section 160 to the moving mechanism 130. The moving mechanism 130 moves the ultrasonic horn 120 to a position notified by the control section 160 and subsequently, the wire feeder 110 is driven so that the capillary 121 provides a front end 111a of the wire 111 onto the electrode pad 21 with the number “1” (step S1 of FIG. 3).

When the front end 111a of the wire 111 is supplied to the electrode pad 21, the control section 160 transmits an oscillation instruction to the oscillator 140 and ultrasonic wave is applied from the vibrator 141 to the ultrasonic horn 120. As a consequence, the capillary 121 is vibrated by the ultrasonic horn 120 and vibration is applied from the capillary 121 to the wire 111, so that the front end 111a of the wire 111 is bonded to the electrode pad 21 (step S2 of FIG. 3).

In this embodiment, as described above, the ultrasonic horn 120 is expanded/contracted in the axial direction and consequently, as shown in part A of FIG. 4, vibration in the axial direction (direction of an arrow A) of the ultrasonic horn 120 is applied to the wire 111 from the capillary 121 so that the wire 111 is bonded to the electrode pad 21 with the number “1”. A step (step S1 and step S2 in FIG. 3) of bonding the front end 111a of the wire 111 to the electrode pad 21 corresponds to an example of the first connecting step in the present invention.

Incidentally, if as shown in part (B) of FIG. 4, the ultrasonic horn 120 is moved up to the inner lead 11 so as to stretch the wire 111 from the electrode pad 21 to the inner lead 11 and with this condition, ultrasonic wave is applied to the ultrasonic horn 120, the wire 111 vibrates largely due to resonance depending on the frequency, resulting in separation of the front end 111a of the wire 111 from the electrode pad 21. This is because the direction of extension of the wire 111 does not coincide with the direction of vibration (direction of the arrow A) applied to the wire 111 from the capillary 121.

The control section 160 shown in FIG. 1 computes a rotation amount of the substrate 10 when an angle θ between a connection line connecting the electrode pad 21 with the inner lead 11 and the axial direction of the ultrasonic horn 120 becomes 0° based on the position of the electrode pad 21 with the number “1” and the position of the inner lead 11 in part (A) of FIG. 4. Subsequently, when the control section 160 gives a drive instruction to the moving mechanism 130, the ultrasonic horn 120 is moved to above the substrate 10 and when a rotation amount and a drive instruction are given to the rotating mechanism 150, the mounting base 151 is rotated by only the computed rotation amount (step S3 in FIG. 3). As a result, the position of the inner lead 11 is set on the axis of the ultrasonic horn 120.

Subsequently, the moving mechanism 130 moves the ultrasonic horn 120 horizontally according to an instruction from the control section 160 so that as shown in part (C) of FIG. 4, the wire 111 is stretched from the electrode pad 21 with the number “1” on the IC chip 20 to the inner lead 11 with the number “1” on the substrate 10 (step S4 in FIG. 3). A step (step S4 in FIG. 3) of stretching the wire 111 from the electrode pad 21 to the inner lead 11 corresponds to an example of the wire stretching step in the present invention.

When the wire 111 is stretched, ultrasonic wave is applied from the vibrator 141 to the ultrasonic horn 120 and then, vibration is applied from the capillary 121 to the wire 111. Because the extension direction of the wire is adjusted to the axial direction of the ultrasonic horn 120, vibration in the extension direction of the wire 111 is applied from the capillary 121 to the wire 111, which avoids such a fault that the wire 111 vibrates largely due to resonance.

When vibration is applied to the wire 111, the wire 111 is bonded to the inner lead 11 (step S5 in FIG. 3). A step (step S4 and step S5 in FIG. 3) of bonding the wire 111 to the inner lead 11 corresponds to an example of the second connecting step in the present invention.

Subsequently, an electrode pad 21 with a number “2” is connected to the inner lead 11, in a similar manner.

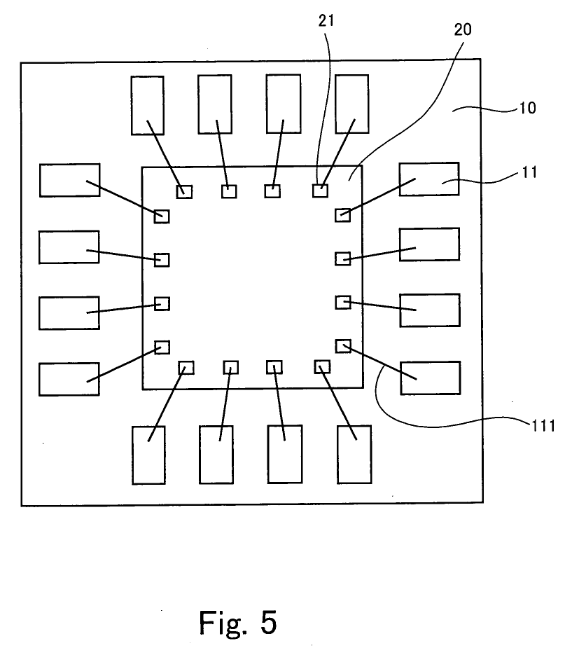

FIG. 5 is a diagram showing the IC chips 20 and the substrate 10 to which the wires 111 are connected.

In this embodiment, after the first bonding of connecting the wire 111 to the electrode pad 21 on the IC chip 20, the direction of vibration applied from the capillary 121 to the wire 111 is matched with the extension direction of the wire 111. Subsequently, the wire 111 is connected to the inner lead 11 on the substrate 10. Consequently, resonance of the wire 111 is avoided thereby preventing such a fault that the wire 111 connected to the electrode pad 21 is separated. Further, because in this embodiment, the wire 111 does not need to be extended wastefully long, complexity of wiring can be suppressed even in case of connecting a multiplicity of electrodes as shown in FIG. 5.

Description of the first embodiment of the present invention is ended and then, a second embodiment of the present invention will be described. Because in the second embodiment of the present invention, the same components as those applied in the first embodiment such as the ultrasonic horn and capillary are applied, description thereof is omitted, while like reference numerals are attached to the same components as the first embodiment and only different points from the first embodiment will be described.

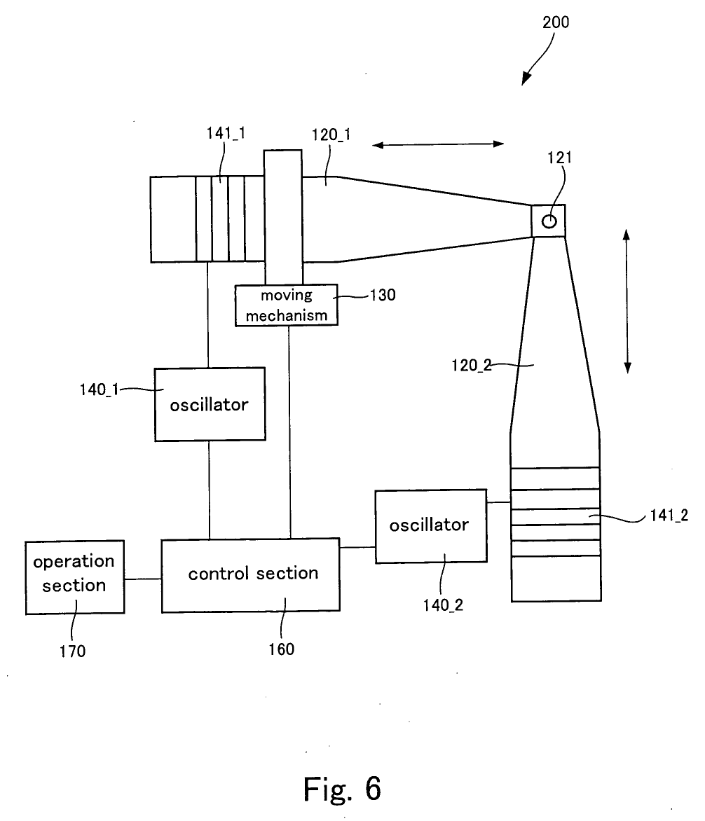

FIG. 6 is a schematic structure diagram of a wire bonding apparatus 200 according to the second embodiment of the present invention.

The wire bonding apparatus 200 shown in FIG. 6 is different from the wire bonding apparatus 100 of the first embodiment, in which two ultrasonic horns 120_1 and 120_2 are mounted on a single capillary 121 while the auxiliary ultrasonic horn 120_2 is fixed perpendicularly to the basic ultrasonic horn 120_1.

The two ultrasonic horns 120_1 and 120_2 are equipped with vibrators 141_1 and 141_2 and vibrations of the vibrators 141_1 and 141_2 are controlled by two oscillators 140 1, 140 2.

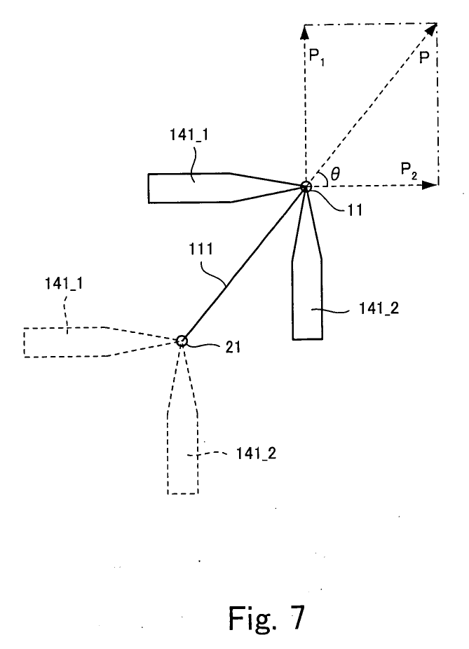

FIG. 7 is a diagram showing the relationship between positions of the electrode pad 21 and inner lead 11 and vibration applied to the wire 111.

In the wire bonding apparatus 200 of this embodiment, the ultrasonic horns 120_1, 120_2 are moved so that the capillary 121 is pressed against the electrode pad 21 on the IC chip 20 and consequently, ultrasonic wave is applied to each of the ultrasonic horns 120_1, 120_2. As a consequence, an end of the wire 111 is bonded to the electrode pad 21 of the IC chip 20 (first bonding).

Subsequently, the ultrasonic horns 120_1, 120_2 are moved so that the capillary 121 is pressed against the inner lead 11 of the substrate 10.

In this embodiment, the rotation of the substrate 10 is not carried out and the amplitude and direction of synthetic vibration applied from the capillary 121 to the wire 111 are controlled by adjusting the amplitude of ultrasonic wave applied to the ultrasonic horns 120_1, 120_2.

Assuming that a desirable amplitude of synthetic vibration is W and an angle formed between the extension direction of the wire 111 and the basic ultrasonic horn 120_1 is θ, the amplitude of ultrasonic P1 to be applied to the basic ultrasonic horn 120_1 is controlled to be W cos θ while the amplitude of ultrasonic wave P2 to be applied to the auxiliary ultrasonic horn 120_2 is controlled to be W sin θ. As a consequence, synthetic vibration P which vibrates at the amplitude W in the same direction as the extension direction of the wire 111 is applied from the capillary 121 to the wire 111.

As a consequence, resonance of the wire 111 can be avoided and the amplitude of the synthetic vibration P applied from the capillary 121 to the wire 111 can be adjusted easily by adjusting the amplitude of ultrasonic wave applied to each of the two ultrasonic horns 120_1, 120_2.

Although an example of adjusting the amplitude and vibration direction of the synthetic vibration using two ultrasonic horns fixed perpendicular to each other has been described above, the plural vibrating member of the present invention is not restricted to those fixed perpendicular to each other and further, a vibrating member equipped with three or more ultrasonic horns may be used.

Further, although an example of applying synthetic vibration to the capillary using two ultrasonic horns has been described, the vibrating member of the present invention may be a vibrating member which vibrates a ultrasonic horn in two directions different from each other and adjusts the vibration direction of the capillary by means of the ultrasonic horn.

Although an example of rotating the mounting base so that the extension direction of the wire coincides with the axial direction of the ultrasonic horn has been described above, the second connecting step in the present invention may adjust the direction of vibration applied to the wire by rotating the ultrasonic horn so as to meet the extension direction of the wire.

### EXAMPLE

Hereinafter, an example of the present invention will be described.

In this example, the wire bonding apparatus 100 shown in FIG. 1 was used and after the front end 111a of the wire 111 was connected to the electrode pad 21 of the IC chip 20 (first bonding), the angle between the extension direction of the wire 111 and the vibration direction of ultrasonic wave was adjusted to 0°, 45° and 90° by rotating the mounting base 151 so as to increase vibration frequency of ultrasonic wave applied to the ultrasonic horn 120 and the wire 111 was bonded to the inner lead 11 of the substrate 10 (second bonding). At the time of the second bonding, stress applied to the front end 111a of the wire 111 connected to the electrode pad 21 of the IC chip 20 was analyzed.

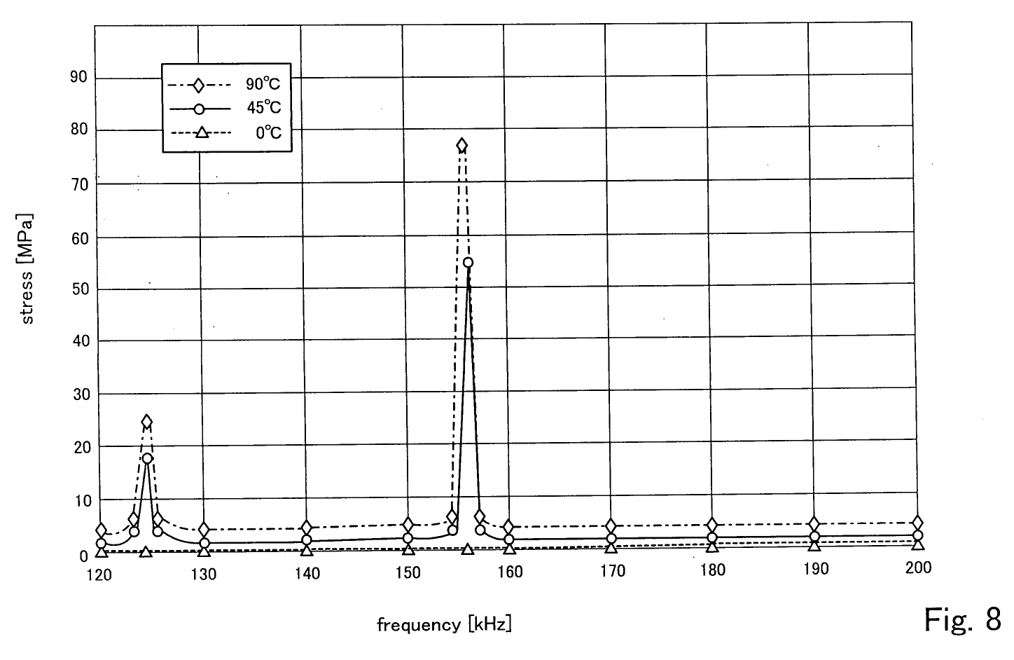

FIG. 8 is a graph showing the relation between the frequency of ultrasonic wave applied to the ultrasonic horn 120 and stress applied to the front end 111a of the wire 111 connected to the electrode pad 21.

In FIG. 8, the frequency [kHz] corresponds to the abscissa axis and stress [MPa] corresponds to the ordinate axis. The analysis result when the angle formed between the extension direction of the wire 111 and the vibration direction of ultrasonic wave is 0° is plotted with a triangle, the analysis result when the angle between the same is 45° is plotted with a circle and an analysis result when the angle between the same is 90° is plotted with a diamond. In FIG. 8, only characteristic result portions of the analysis result are plotted.

As shown in FIG. 8, when the angle formed between the extension direction of the wire 111 and the vibration direction of ultrasonic wave is 45° and 90°, the wire 111 resonates at a frequency of 158 kHz so that a large stress is applied to the front end 111a of the wire 111.

However, in case where the angle formed between the extension direction of the wire 111 and the vibration direction of ultrasonic wave was 0°, stress applied to the ultrasonic horn 120 was substantially constant at 0 [MPa], even if the frequency of ultrasonic wave applied to the ultrasonic horn 120 was increased. Accordingly, the analysis result demonstrates usability of the present invention that the fault of separation of the bonded wire 111 due to resonance can be avoided by applying vibration in the extension direction of the wire 111.

What is claimed is:

1. A wire bonding method comprising:
a first connecting step of supplying an end of wire for electric wiring to a first electrode on an IC chip and applying vibration to the wire, thereby connecting the end of the wire to the first electrode;
a wire stretching step of stretching the wire whose end is connected to the first electrode up to a second electrode on a different member from the IC chip; and
a second connecting step of connecting the wire to the second electrode by applying vibration, in an extension direction of the wire stretched from the first electrode to the second electrode, to a portion of the wire overlapping the second electrode.

2. The wire bonding method according to claim 1, executing the first connecting step, the wire stretching step and the second connecting step with a vibrating unit, the vibrating unit comprising:
a capillary which applies vibration to the wire supplied to an electrode; and
plural vibrating members which vibrate the capillary in different vibration directions,
wherein the second connecting step is a step of causing the capillary to apply vibration in the extension direction to the portion of the wire overlapping the second electrode, by adjusting amplitude of each vibration of the plural vibrating members.

3. The wire bonding method according to claim 2, the plural vibrating members comprising:
a first vibrating member which vibrates in a predetermined first direction; and
a second vibrating member which vibrates in a second direction perpendicular to the first direction,
wherein the second connecting step is a step of, when assuming that an angle formed between the extension direction and the first direction is θ and the amplitude of vibration applied to the wire is W, vibrating the first vibrating member at an amplitude of W cos θ while vibrating the second vibrating member at an amplitude of W sin θ, thereby causing the capillary to apply synthetic vibration by the first vibrating member and the second vibrating member to the portion of the wire overlapping the second electrode.

4. The wire bonding method according to claim 1, wherein the first connecting step is a step of applying ultrasonic wave to the wire and the second connecting step is a step of applying ultrasonic wave to the portion of the wire overlapping the second electrode.

5. A wire bonding apparatus comprising:
a mounting base on which an IC chip having a first electrode and a member to be connected are mounted, the member being different from the IC chip and having a second electrode to be connected to the first electrode;
a vibrating unit including a capillary and a vibrating member which vibrates the capillary, the capillary supplying wire for electric wiring to an electrode and connecting the wire to the electrode by applying vibration to the wire; and
a control unit which causes the capillary to:
supply an end of the wire to the first electrode on an IC chip mounted on the mounting base and connect the end of the wire to the first electrode by applying vibration to the wire;
stretch the wire whose end is connected to the first electrode up to a second electrode on the member; and
apply vibration in an extension direction of the wire to a portion thereof overlapping the second electrode of the wire stretched up to the second electrode, thereby connecting the wire to the second electrode.

6. The wire bonding apparatus according to claim 5,
wherein the vibrating unit includes plural vibrating members which vibrate the capillary to vibrate in different directions, and
wherein the control unit causes the capillary to apply vibration in the extension direction to the portion of the wire overlapping the second electrode, by adjusting the amplitude of each vibration of the plural vibrating members after the wire is stretched to the second electrode.

7. The wire bonding apparatus according to claim 6, the plural vibrating members comprising:
a first vibrating member which vibrates in a predetermined first direction; and
a second vibrating member which vibrates in a second direction perpendicular to the first direction,
wherein the control section, when it is assumed that an angle formed between the extension direction and the first direction is θ and the amplitude of vibration applied to the wire is W, vibrates the first vibrating member at an amplitude of W cos θ while vibrating the second vibrating member at an amplitude of W sin θ, thereby causing the capillary to apply synthetic vibration by the first vibrating member and the second vibrating member to the portion of the wire overlapping the second electrode.

8. The wire bonding apparatus according to claim 5, wherein the vibrating unit applies ultrasonic wave to the wire.

9. A semiconductor device which is manufactured through:
a first connecting step of supplying an end of wire for electric wiring to a first electrode on an IC chip and connecting the wire to the first electrode by applying vibration to the wire;
a wire stretching step of stretching the wire whose end is connected to the first electrode up to a second electrode on a different member from the IC chip; and
a second connecting step of connecting the wire to the second electrode by applying vibration, in an extension direction of the wire stretched from the first electrode to the second electrode, to a portion of the wire overlapping the second electrode.

10. The semiconductor device according to claim 9, wherein the first connecting step is a step of applying ultrasonic wave to the wire and the second connecting step is a step of applying ultrasonic wave to the portion of the wire overlapping the second electrode.
